(19) United States
(12) Patent Application Publication
(10) Pub. No.: US 2008/0128864 A1
(43) Pub. Date: Jun. 5, 2008

(54) Semiconductor chip and method of producing the same

(75) Inventor: Sung-dae Cho, Asan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/987,424

(22) Filed: Nov. 30, 2007

(30) Foreign Application Priority Data
Nov. 30, 2006 (KR) 10-2006-0120062

(51) Int. Cl. H01L 29/06; H01L 21/304

(52) U.S. Cl. 257/620; 438/462; 257/E21.238; 257/E29.022

(57) ABSTRACT

Provided are a semiconductor chip and a method of producing the semiconductor chip. The chip and the method of producing the chip may remove or reduce chip performance issues involving current leakage and/or short-circuit malfunctions caused by inadvertent or intentional contacting of bonding wires with a surface and/or edge of the semiconductor chip. Also, the thickness of a semiconductor package in which semiconductor chips are stacked may be reduced.

### PRIORITY STATEMENT

This application claims priority under 35 U.S.C. § 119 to Korean Patent Application No. 10-2006-0120062, filed on Nov. 30, 2006, in the Korean Intellectual Property Office, the entire contents of which are incorporated herein by reference.

### BACKGROUND

1. Field

Example embodiments relate to a semiconductor chip and a method of producing the same, for example, to a semiconductor chip capable of removing or reducing a side-effect such as a leakage current or a malfunction and/or a short-circuit of the semiconductor chip caused by the contacting of a bonding wire with a surface and/or edge of the semiconductor chip and a method of producing the same.

2. Description of the Related Art

Semiconductor devices may be required to be more compact and/or thinner and/or have higher capacities, as the electronic products in which the semiconductor devices are used become thinner and/or more compact. Conditions for stacking several semiconductor chips and connecting a bonding pad to a lead frame using bonding wires may become complicated, using such thinner and more compact design. Thus, the bonding wires directly contacting the edges of the semiconductor chips may cause the semiconductor chip to malfunction and/or short-circuit.

Referring to FIG. 1A, a conventional circuit is formed on a semiconductor substrate to form semiconductor die 10a and 10b which are to be separate semiconductor dies. A passivation layer 12 protects the substrate, except for bonding pads 14. A scribe lane 20 exists between the semiconductor dies 10a and 10b.

Referring to FIG. 1B, conventional dicing may be performed using a cutter, for example a sawing blade (not shown), to separate the semiconductor dies 10a and 10b from each other. Because a thickness of the cutter must be narrower than a width of the scribe lane 20, such that a portion of the scribe lane 20 remains as shown in FIG. 1B. Also, the passivation layer 12 may be non-conductive, while the portion of the scribe lane 20 may be conductive.

Referring to FIG. 1C, the conventional diced semiconductor chip may be placed on a die pad 40, and the bonding pads 14 may be bonded to lead lines 40 using a bonding wire 50 in order to package the diced semiconductor chips.

Referring to FIG. 1D, when a conventional semiconductor chip 60 may be additionally stacked on the semiconductor chip, a bonding wire 50′ may be pressed to be deformed so as to contact an edge (portion A of FIG. 1D) of the semiconductor chip. In this case, a current may leak between two stacked semiconductor chips, and the semiconductor chips may malfunction and/or short-circuit.

Although semiconductor chips may be stacked (affixed, one on top of the other) differently from FIG. 1D, conditions for wire bonding may still be harsh with the tendency to make semiconductor chips more compact, thinner, and/or of higher capacity. Thus, the bonding wire 50 of FIG. 1C may still contact an edge of the semiconductor die 10a.

Such an inadvertent or unavoidable contact of a bonding wire with a conductive portion of a semiconductor may affect yield of semiconductor devices and thus must be managed. Thus, a semiconductor chip having a structure capable of preventing a short-circuit between a bonding wire and a semiconductor die and a method of producing the semiconductor chip is advantageous.

### SUMMARY

Example embodiments provide a semiconductor chip, and method of making, having a structure capable of preventing or reducing a side-effect such as a current leakage or a malfunction and/or a short-circuit of the semiconductor chip caused by inadvertent or intentional contact of a bonding wire with a surface and/or edge of the semiconductor chip.

Example embodiments also provide a method of producing the semiconductor chip.

Example embodiments also provide a semiconductor package in which the semiconductor chips are stacked (placed one on top of the other).

According to example embodiments, there is provided a semiconductor chip including a semiconductor die at least a portion of the edge of which may be formed of an insulating material.

A surface of the insulating material may exist substantially on the same plane as a surface of the semiconductor die.

At least portions of the upper edge and portions of the lower edge may be formed of insulating materials. The insulating material of the upper edge and the insulating material of the lower edge may be connected to each other. At least a portion of the edge may be selectively formed of an insulating material from the upper edge to the lower edge.

The edge of the semiconductor die closest to a bonding pad may be formed of the insulating material.

The insulating material may be an electrically nonconductive material comprising a thermosetting resin.

According to example embodiments, there is provided a method of producing a semiconductor chip having a structure capable of preventing a short-circuit of wires, including: providing a wafer including a plurality of semiconductor dies separated from each other through a scribe lane; forming a opening, via, cavity, void or recessed space, in at least a portion of the scribe lane; filling an insulating material into the opening, via, cavity, void or recessed space; and cutting a center of the insulating material along the scribe lane using a cutter. It should be noted that the terms opening or via, are more synonymous with a penetration that goes through a substrate, such that at least a portion of the opening or via penetrate through both the upper and lower surface of the semiconductor die. The terms cavity, void, or recessed space, are more synonymous with a recessed area on the upper and/or lower portion of the substrate, but that do not penetrate all the way through the semiconductor die. A cavity, void, or recessed area may become an opening or via, by puncturing the substrate such that the cavity extends at least partially from the upper to the lower surface of the semiconductor die. A opening, via, cavity, void, or recess may be configured into any desired shape, such that it may be convex, concave, polygonal, square, or rectangular in shape. A recess may be configured into a “dished” shape, a slit, a “U” or “V” shape, or any other shape that may provide a void whereby insulation may then be filled into the void.

A width of the via or recessed space may be wider than a width of the cutter and narrower than a width of the scribe lane.

A width of the via or recessed space may be narrower than a width of the scribe lane or wider than the width of the scribe lane within a range in which the via or recessed space does not encroach a circuit part formed in the semiconductor dies.

The formation of the via or recessed space may include irradiating a laser beam to form the via or recessed space.

The formation of a recessed space may include forming a recessed area in both the upper and lower portions of the wafer in an area of the scribe lane. A width of the recessed area formed in the lower portion of the wafer may be wider than a width of the recessed portion formed in the upper portion of the wafer.

The formation of a via may include forming a penetration from an upper surface of the scribe lane to a lower surface of the scribe lane in at least a portion of the scribe lane.

According to an example embodiment, there is provided a multi-chip package in which the semiconductor chips described above are stacked (i.e., layered, or placed one on top of the other).

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIGS. 1A through 1D are cross-sectional views illustrating a process of packaging a semiconductor chips according to conventional art.

FIGS. 2A through 2E are perspective views and cross-sectional views of semiconductor chips according to example embodiments.

FIGS. 3A through 3E are cross-sectional views sequentially illustrating a method of producing a semiconductor chip according to example embodiments.

FIGS. 4A through 4D are cross-sectional views sequentially illustrating a method of producing a semiconductor chip according to example embodiments.

FIGS. 5A through 5C are cross-sectional views sequentially illustrating a method of producing a semiconductor chip according to example embodiments.

FIG. 6 is a cross-sectional view of a semiconductor chip package according to example embodiments.

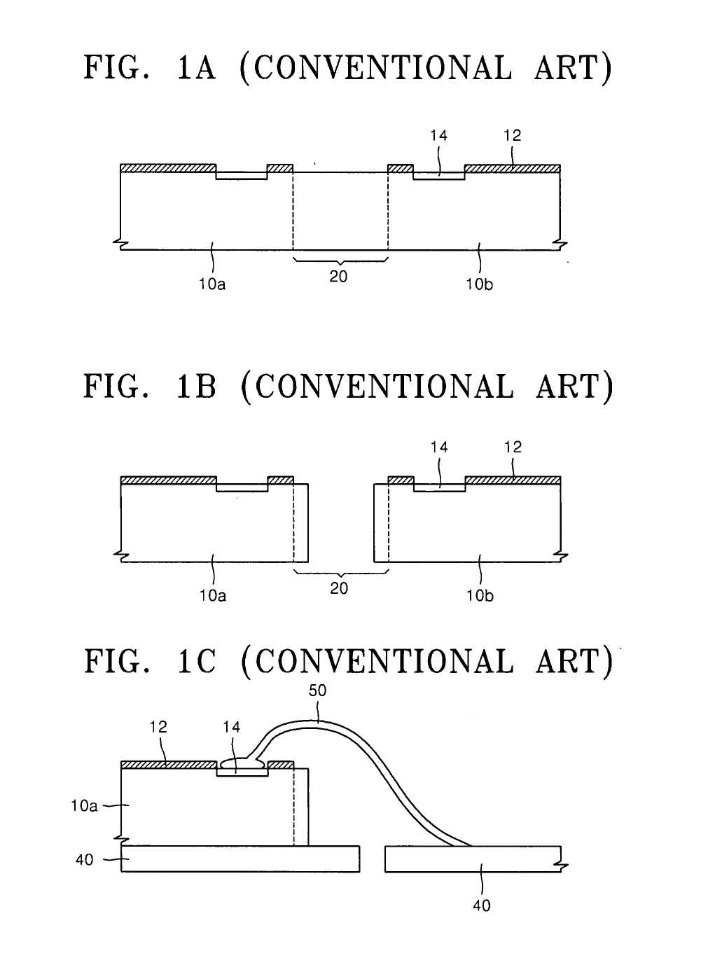

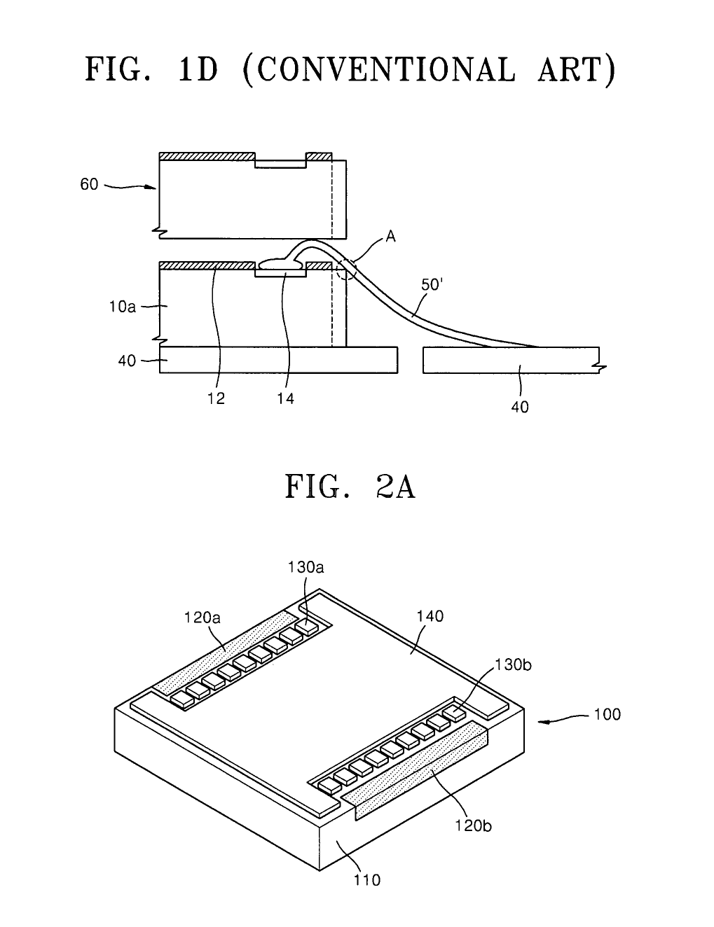

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their description will be omitted.

According to example embodiments, there is provided a semiconductor chip including a semiconductor die, at least a portion of the edge of which is formed of an insulating material. Here, the edge may be defined to include any portion of the substrate that may include an upper and/or lower surface of a substrate along with a side of the semiconductor chip. Thus, the meaning of the expression “at least a portion of an edge may be formed of an insulating material” may be understood as meaning “an area of a substrate including an upper (or lower) surface and a side surface of the semiconductor die which may be formed of an insulating material.”

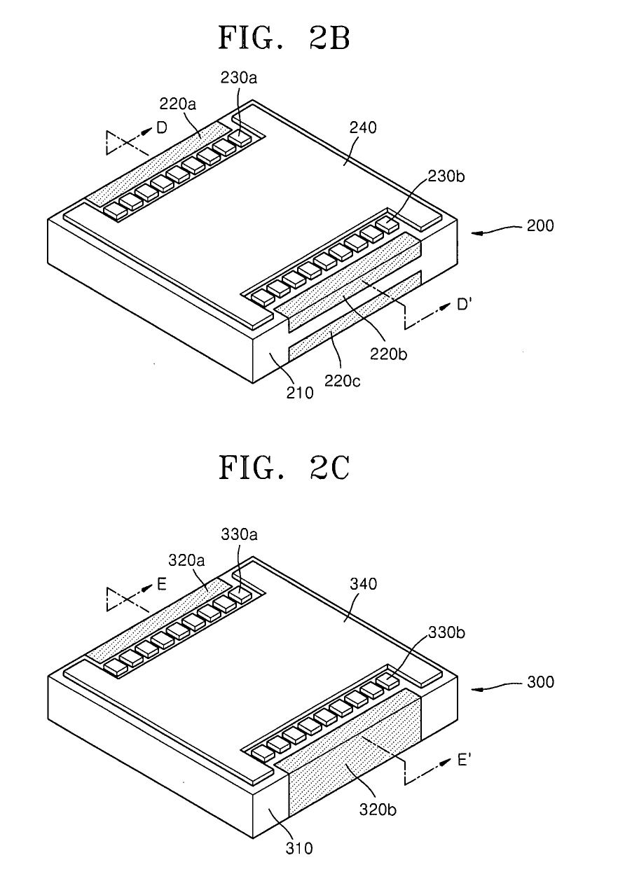

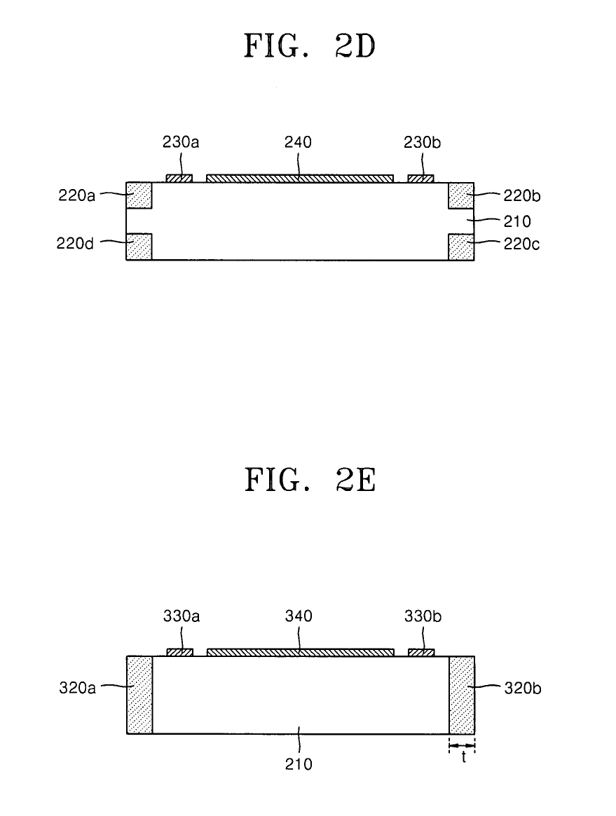

FIG. 2A is a perspective view of a semiconductor chip 100 according to example embodiments. The semiconductor chip 100 may include a semiconductor die 110 and upper edges which may be formed of insulating materials 120a and 120b at portions of both edges of the semiconductor die 110 facing each other. As shown in FIG. 2A, a portion of an upper surface of the semiconductor chip 100 may be protected by a passivation layer 140, while bonding pads 130a and 130b may be exposed. The upper edges formed of the insulating materials 120a and 120b may be the closest edge from the portions on which the bonding pads 130a and 130b are formed.

When cross-sections of the insulating materials 120a and 120b are taken in a direction perpendicular to the upper edges, the insulating materials 120a and 120b may be polygonal in shape, and in particular, they may be shaped into squares. A partial cross-sectional view taken along a line D-D′ of FIG. 2B is shown in FIG. 2D in order to depict the shapes of the insulating material (depicted in FIG. 2D as 220a/b/c/d) in more detail. For example, insulating materials 220b and 220c may have rectangular cross-sections as shown in FIG. 2D. The rectangular cross-sections may be substantially the same at any cross-section taken at an arbitrary point of edges.

Insulating materials as described above may be nonconductive materials but are not limited by material type. However, the insulating materials may be electrically nonconductive materials including thermosetting resins. Alternatively, the insulating materials may be polyimide resins.

For example, surfaces of the insulating materials 120a and 120b may be substantially on the same plane as a surface of the semiconductor die 110 as indicated in FIG. 2A. “The surfaces of the insulating materials 120a and 120b are substantially on the same plane as the surface of the semiconductor die 110” may mean that there is no elevation difference between the surfaces of the insulating materials 120a and 120b and the surface of the semiconductor die 110. Also, the expression may mean that although an elevation difference may exist between the surfaces of the insulating materials 120a and 120b and the surface of the semiconductor die 110, the elevation difference does not interfere with the objectives of example embodiments.

FIG. 2B is a perspective view of a semiconductor chip 200 according to example embodiments. Referring to FIG. 2B, a surface of a semiconductor die 210 may be protected by a passivation layer 240, and bonding pads 230a and 230b may be formed on the surfaces of the semiconductor die 210. Upper edges of the semiconductor die 210, located closest to the bonding pads 230a and 230b, may be formed of the insulating materials 220a and 220b, and lower edges of the semiconductor die 210 may be formed of an insulating material 220c. Although not expressly illustrated in FIG. 2B, the lower edge corresponding to the upper edge formed of the insulating material 220a may be formed of an insulating material.

FIG. 2C is a perspective view of a semiconductor chip 300 according to example embodiments. Referring to FIG. 2C, a surface of a semiconductor die 310 may be protected by a passivation layer 340, and bonding pads 330a and 330b may be formed on the surface of the semiconductor die 310. Upper edges and lower edges of the semiconductor die 310 closest to the bonding pads 330a and 330b may be formed of insulating materials and connected to each other. For example, the upper and lower edges of at least portions of the semiconductor die 310 may be formed of insulating materials 320a and 320b.

Cross-sections taken along a line E-E′ of FIG. 2C are shown in FIG. 2E in order to describe the insulating materials (depicted in FIG. 2E as 320a and 320b) in more detail. As shown in FIG. 2E, the insulating material 320b extends from the upper edge to the lower edge at a substantially constant thickness t.

As described above, if edges are formed of insulating materials 120a and 120b, 220a, 220b, and 220c, or 320a and 320b, bonding wires extending from the bonding pads 130a and 130b, 230a and 230b, or 320a and 320b may contact edges of a semiconductor chip due to external factors such as tight semiconductor design conditions or through compression or interference caused by another semiconductor chip. However, a leakage current may be reduced or prevented, or a semiconductor device may be prevented from malfunctioning and/or short-circuiting due to contact of the bonding wires with the edge of the semiconductor chip.

According to example embodiments, there may be provided a method of producing a semiconductor chip having a structure capable of preventing a short-circuit of a wire, including: providing a wafer including a plurality of semiconductor dies separated by a scribe lane; forming a via or recessed portion in at least a portion of the scribe lane; filling an insulating material into the via or recessed portion; and dicing the scribe lane using a cutter.

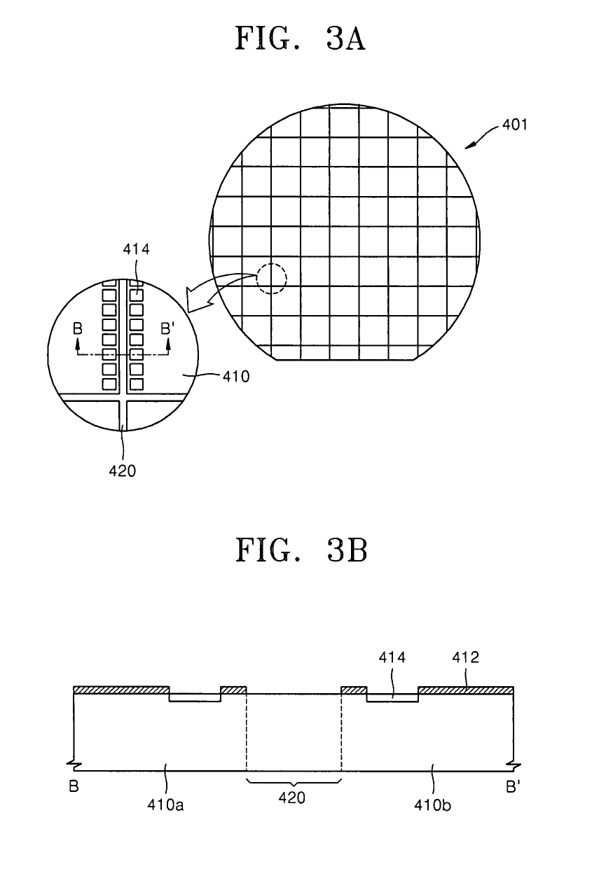

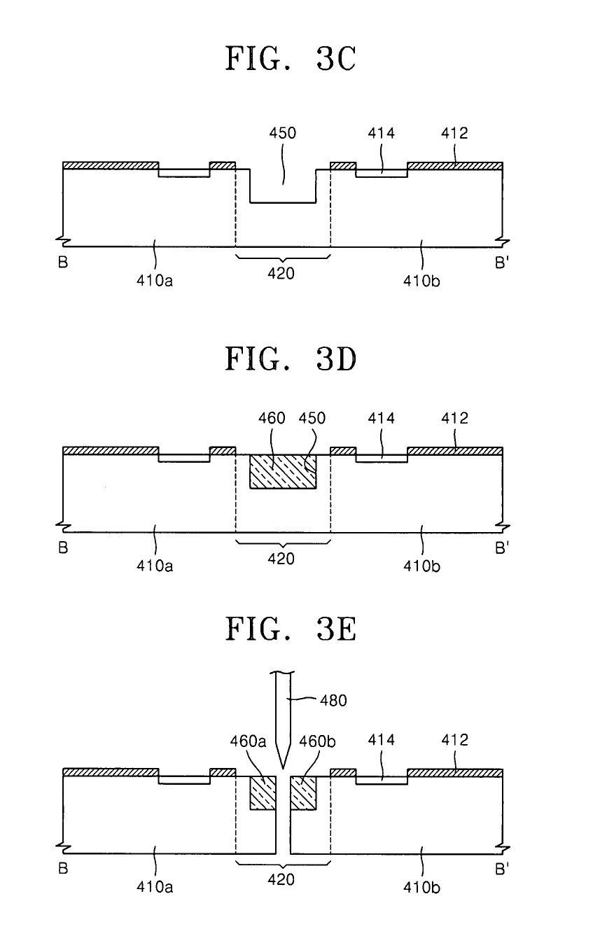

FIGS. 3A through 3E are cross-sectional views illustrating a method of producing a semiconductor chip according to example embodiments.

FIG. 3A illustrates a wafer 401 in which a circuit may be formed on a semiconductor substrate and a passivation layer is formed thereon. Referring to FIG. 3A, bonding pads 414 may be formed along a periphery of semiconductor dies 410, and a scribe lane 420 may be formed among the semiconductor dies 410.

FIG. 3B is a cross-sectional view taken along a line B-B′ of FIG. 3A. Referring to FIG. 3B, two semiconductor dies 410a and 410b may be adjacent to each other with the scribe lane 420 interposed therebetween and both include the bonding pads 414. Also, a circuit part is protected by a passivation layer 412.

Referring to FIG. 3C, a recessed portion 450 is formed along the scribe lane 420 in at least a portion of the scribe lane 420. The recessed portion 450 may be formed using a laser, but is not limited to this. If a width of the recessed portion 450 is too wide, the circuit part of the semiconductor dies 410a and 410b may be damaged. Thus, the width of the recessed portion 450 may be narrower than a width of the scribe lane 420. However, the width of the recessed portion 450 may be selectively narrower or wider than the width of the scribe lane 420, so long as the recessed area is not encroaching the circuit part of the semiconductor dies 410a and 410b. A depth of the recessed portion 450 is not specifically limited and may be appropriately selected in consideration of manufacturing convenience, etc.

As shown in FIG. 3D, an insulating material 460 may be filled in the recessed portion 450. The insulating material 460 may be directly injected into the recessed portion 450 using an injector or may be formed using a mask.

A method of forming the insulating material 460 using a mask is as follows. A layer of an insulating material is formed within the recessed area, a photoresist layer is formed on the layer, and a portion of the photoresist layer from which the insulating material is to be removed may be removed using exposure and development. An exposed portion of the insulating material may be removed using an acid or the like, and the photoresist layer is then ashed to obtain the insulating material filled in the recessed portion 450.

After the insulating material 460 is filled in the recessed portion 450, a center of the insulating material 460 may be cut along the scribe lane 420 using a cutter 480 as shown in FIG. 3E. This process may be a dicing process used in a general process of producing a semiconductor chip, and the cutter 480 may be a sawing blade, but the process is not limited to this. A width of the cutter 480 may be narrower than a width of the recessed portion 450 filled with the insulating material 460.

When cutting is completed, the semiconductor dies 410a and 410b may be separated from each other, and the insulating material 460 may be divided into insulating materials 460a and 460b. Because the insulating materials 460a and 460b may be positioned at an edge of a semiconductor chip 410b, even though bonding wires extending from the bonding pads 414 may contact the edge of the semiconductor chip 410b, a leakage current, a short-circuit and/or malfunction of a semiconductor device will not occur.

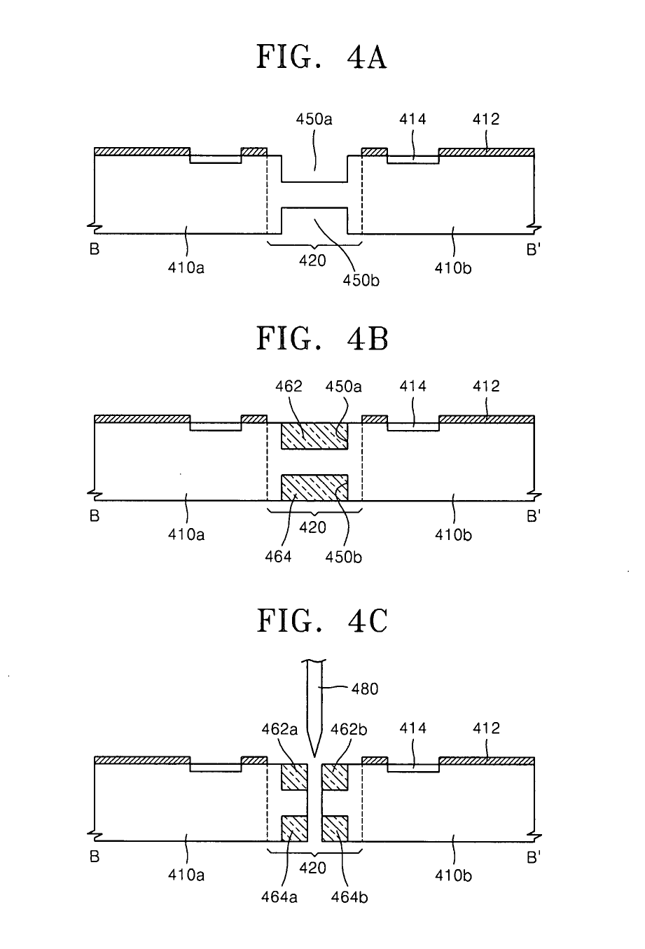

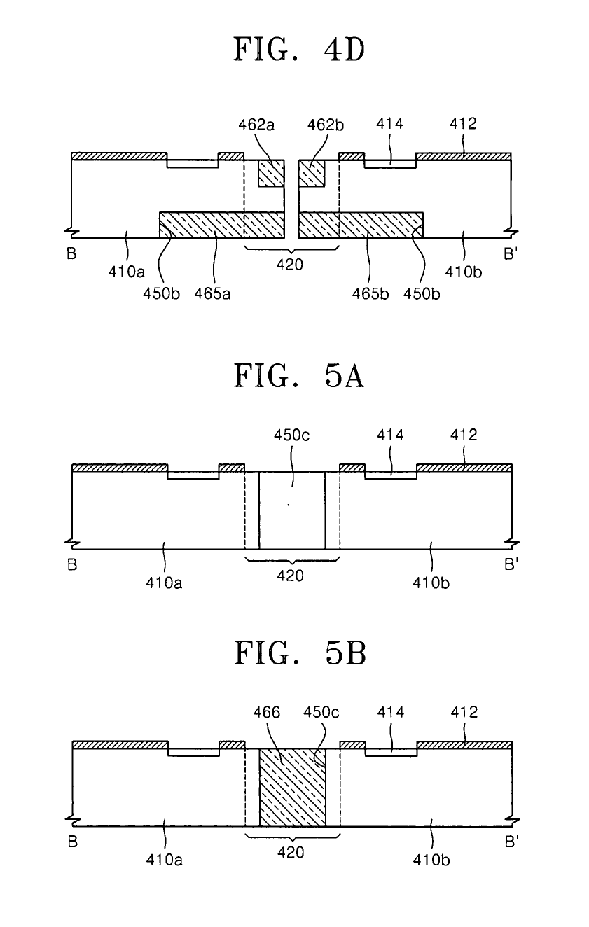

A method of producing a semiconductor chip according to example embodiments will now be described with reference to FIGS. 4A through 4C.

A process of providing a wafer, in this example, is the same as that described in conjunction with reference to FIGS. 3A and 3B, and thus its detailed description will be omitted herein. Referring to FIG. 4A, recessed portions 450a and 450b are formed on upper and lower surfaces of the wafer along a scribe lane 420. The recessed portions 450a and 450b may be formed in the same area of the scribe lane 420, in the upper and lower surfaces of the wafer, correspondingly.

The recessed portion 450b is formed in a rear surface of the wafer. Therefore, the width of the recessed portion 450b does not need to depend on a width of the scribe lane 420, as a wider recessed portion 450b would not encroach on a circuit part.

Referring to FIG. 4B, insulating materials 462 and 464 are filled in the recessed portions 450a and 450b. The insulating materials 462 and 464 may be filled using the same method as that described in the previous method, and thus its description will be omitted herein.

Referring to FIG. 4C, centers of the insulating materials may be cut along the scribe lane 420 using a cutter 480 to separate the semiconductor dies 410a and 410b from each other. This process may be a dicing process used in a general process of producing a semiconductor chip, and the cutter 480 may be a sawing blade, but the process is not limited to this. The width of the cutter 480 must be narrower than a width of the recessed portion 450a filled with the insulating material 462.

When cutting is completed, the semiconductor dies 410a and 410b may be separated from each other, and the insulating materials 462 and 464 may also be divided into insulating materials 462a, 462b, 464a, and 464b. Also, the insulating materials 462a, 462b, 464a, and 464b may be positioned at an edge of a semiconductor chip 410b. Thus, although bonding wires extending from bonding pads 414 may inadvertently or intentionally contact the edge of the semiconductor chip 410b, a leakage current, a short-circuit and/or malfunction of a semiconductor device will not occur.

If a width of the recessed portion 450b is wider than the width of the scribe lane 420 as previously described, the recessed portion 450b may be configured as shown in FIG. 4D. The bonding pads 414 may be formed near the edges of the semiconductor dies 410a and 410b or may be formed on centers of the semiconductor dies 410a and 410b. If the bonding pads 414 are formed near the edges of the semiconductor dies 410a and 410b, the recessed portion 450b may extend to a portion of the semiconductor die 410b under the bonding pads 414. Thus, although bonding wires extending from bonding pads on a lower semiconductor chip may inadvertently or intentionally contact a lower surface of an upper semiconductor chip when the upper and lower semiconductor chips are stacked, an insulation property may be maintained.

Accordingly, semiconductor chips may be stacked regardless of any inadvertent or intentional contact with bonding wires, and thus it is advantageous in reducing a thickness of a stacked package.

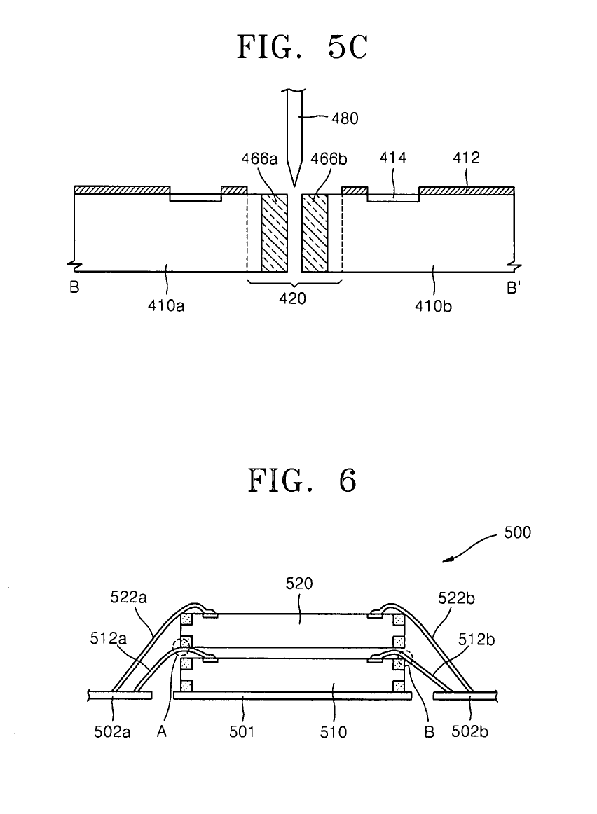

A method of producing a semiconductor chip according to example embodiments, will now be described with reference to FIGS. 5A through 5C.

A process of providing a wafer, in this example, is the same as that described in conjunction with reference to FIGS. 3A and 3B, and thus its detailed description will be omitted herein. Referring to FIG. 5A, a via 450c may be formed in the wafer along a scribe lane 420. Although the via 450c has a hole shape penetrating the wafer, semiconductor dies 410a and 410b are not separated from each other by the via 450c. In other words, the via 450c may be formed only in an area of the scribe lane 420 toward which bonding wires (not shown) may extend from bonding pads 414. Also, a via is not formed in an other area of the scribe lane 420, as semiconductor dies 410a and 410b may be connected to each other through the other area of the scribe lane 420.

A width of the via 450c must be narrower than a width of the scribe lane 420 so as not to damage a circuit part formed in the semiconductor dies 410a and 410b.

Referring to FIG. 5B, an insulating material 466 is filled into the via 450c. The insulating material 466 may be filled using the same method as that described in the previous embodiment, and thus its description will be omitted herein.

Referring to FIG. 5C, a center of the insulating material 466 is cut along the scribe lane 420 using a cutter 480 to separate the semiconductor dies 410a and 410b from each other. This process may be a dicing process used in a general process of producing a semiconductor chip, and the cutter 480 may be a sawing blade, although the process is not limited to this. A width of the cutter 480 must be narrower than a width of the via 450c filled with the insulating material 466.

When cutting is completed, the semiconductor dies 410a and 410b may be separated from each other, and the insulating material 466 may also be divided into insulating materials 466a and 466b. Also, the insulating materials 466a and 466b may be positioned at an edge of a semiconductor chip 410b. Thus, although bonding wires extending from bonding pads 414 may in advertently contact the edge of the semiconductor chip 410b, a leakage current, a short-circuit and/or malfunction of a semiconductor device will not occur.

According to example embodiments, there may be provided a multi-chip package in which semiconductor chips as described above are stacked. FIG. 6 is cross-sectional view of a multi-chip package 500 according to example embodiments.

A first semiconductor chip 510 may be bonded to a die pad 501, and the first semiconductor chip 510 may also be connected to lead lines 502a and 502b through first bonding wires 512a and 512b. A second semiconductor chip 520 may be positioned above the first semiconductor chip 510 and connected to the lead lines 502a and 502b through second bonding wires 522a and 522b.

As shown in portion A of FIG. 6, the first bonding wire 512a is contacting a lower surface of a second semiconductor chip 520. In example embodiments, an insulating material prevents a leakage current, a short-circuit, etc. As shown in portion B of FIG. 6, the first bonding wire 512b is contacting an upper surface of the first semiconductor chip 510. In example embodiments, the insulating material prevents a leakage current, a short-circuit, etc.

As described above, in a semiconductor chip and a method of producing the semiconductor chip according to example embodiments, a side-effect such as a leakage current and a malfunction of a semiconductor chip and/or a short-circuit of a circuit caused by a bonding wire inadvertently or intentionally contacting a surface and/or edge of a semiconductor chip may be removed and/or reduced. Also, the thickness of a semiconductor package in which semiconductor chips are stacked can be reduced, using the example process.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A semiconductor chip, wherein at least a portion of an edge of a semiconductor die included in the semiconductor chip includes an insulating material.

2. The semiconductor chip of claim 1, wherein a surface of the insulating material is substantially on the same plane as at least one surface of the semiconductor die.

3. The semiconductor chip of claim 1, wherein at least portions of an upper edge and portions of a lower edge include insulating materials.

4. The semiconductor chip of claim 3, wherein the insulating material of the upper edge and the insulating material of the lower edge are connected to each other.

5. The semiconductor chip of claim 4, wherein at least portion of the edge is formed of an insulating material from the upper edge to the lower edge.

6. The semiconductor chip of claim 1, wherein an edge closest to a portion of the semiconductor die on which bonding pads are formed is formed of the insulating material.

7. The semiconductor chip of claim 1, wherein the insulating material is an electrically nonconductive material including a thermosetting resin.

8. A method of producing a semiconductor chip, comprising:
providing a wafer including a plurality of semiconductor dies separated from each other by a scribe lane;
forming a recessed portion in at least a portion of the scribe lane;
filling an insulating material into the recessed portion; and
cutting a center of the insulating material along the scribe lane using a cutter.

9. The method of claim 8, wherein a width of the recessed portion is wider than a width of the cutter and narrower than a width of the scribe lane.

10. The method of claim 8, wherein a width of the recessed portion is narrower than a width of the scribe lane or wider than the width of the scribe lane within a range in which the recessed portion does not encroach a circuit part of the semiconductor die.

11. The method of claim 8, wherein forming the recessed portion includes irradiating a laser beam to form the recessed portion.

12. The method of claim 8, wherein forming the recessed portion includes forming recessed portions in upper and lower portions of the wafer in an area of the scribe lane.

13. The method of claim 12, wherein a width of the recessed portion formed in the lower portion of the wafer is wider than a width of the recessed portion formed in the upper portion of the wafer.

14. The method of claim 8, wherein forming the recessed portion includes forming a via penetrating from an upper surface of the scribe lane to a lower surface of the scribe lane in at least a portion of the scribe lane.

15. A multi-chip package comprising a plurality of stacked semiconductor chips of claim 1.
